(19) United States
(12) Patent Application Publication
(10) Pub. No.: US 2020/0371393 A1
(43) Pub. Date: Nov. 26, 2020

(54) TILING DISPLAY DEVICE AND MANUFACTURING METHOD THEREOF

(71) Applicant: E Ink Holdings Inc., HSINCHU (TW)

(72) Inventors: Chen-Yun MA, HSINCHU (TW); Sheng-Long LIN, HSINCHU (TW); Ian FRENCH, HSINCHU (TW)

(21) Appl. No.: 15/931,610

(22) Filed: May 14, 2020

(30) Foreign Application Priority Data
May 20, 2019 (TW) 108117380

(51) Int. Cl. G02F 1/1333; H01L 27/12; H01L 23/544; G02F 1/167; G02F 1/1368; G02F 1/16755

(52) U.S. Cl. CPC G02F 1/133351; H01L 27/1218; H01L 27/1262; H01L 23/544; G02F 1/167; G02F 2202/28; G02F 1/16755; G02F 1/133305; H01L 2223/54426; G02F 2201/50; G02F 1/1368

(57) ABSTRACT

A tiling display device includes a support element, plural thin film transistor (TFT) substrates, a front panel laminate (FPL), and a protection sheet. The TFT substrates are located on the support element and are adjacent to each other. The front panel laminate is located on the TFT substrates and has a light transmissive film, a transparent conductive layer, and a display medium layer. The transparent conductive layer is located on a bottom surface of the light transmissive film. The display medium layer is located between the transparent conductive layer and the TFT substrates. The protection sheet is located on a top surface of the front panel laminate.

### CROSS-REFERENCE TO RELATED APPLICATION

This application claims priority to Taiwan Application Serial Number 108117380, filed May 20, 2019, which is herein incorporated by reference in its entirety.

### BACKGROUND

### Field of Invention

The present invention relates to a tiling display device and a manufacturing method of the tiling display device.

### Description of Related Art

The current reflective display device needs to be formed by splicing several reflective display panels so as to achieve a purpose for large size display. However, a gap would be produced between the adjacent panels because of the process tolerance and the assembly tolerance of each component. For example, a cutting tolerance of a thin film transistor (TFT) substrate, an interval (safety tolerance) between an upper protection sheet and the thin film transistor substrate, and an interval (safety tolerance) between a front panel laminate and the thin film transistor. These tolerances would accumulate to cause the joint of the tiling display device too big, affecting vision effect.

### SUMMARY

One aspect of the present disclosure is to provide a tiling display device.

According to one embodiment of the present disclosure, a tiling display device includes a support element, a plurality of thin film transistor substrates, a front panel laminate, and a protection sheet. The thin film transistor substrates are located on the support element and adjacent to each other. The front panel laminate is located on the thin film transistor substrates and includes a light transmissive film, a transparent conductive layer and a display medium layer. The transparent conductive layer is located on a bottom surface of the light transmissive film, and the display medium layer is located between the transparent conductive layer and the thin film transistor substrates. The protection sheet is located on a surface of the front panel laminate facing away from the thin film transistor substrates.

According to one embodiment of the present disclosure, an interval between the two adjacent thin film transistor substrates is in a range from 10 μm to 200 μm.

According to one embodiment of the present disclosure, the tiling display device further includes an adhesive layer. The adhesive layer is located between the thin film transistor substrates and the support element.

According to one embodiment of the present disclosure, the adhesive layer is an optical clear adhesive or a double-side adhesive.

According to one embodiment of the present disclosure, the support element is a flexible substrate.

According to one embodiment of the present disclosure, the support element is made of a material including glass, acrylic, carbon fiber, graphene or metal.

According to one embodiment of the present disclosure, an area of the support element is greater than a total area of the thin film transistor substrates.

According to one embodiment of the present disclosure, a total area of the thin film transistor substrates is greater than an area of the protection sheet, and the area of the protection sheet is greater than an area of the front panel laminate.

According to one embodiment of the present disclosure, a edge of each of the thin film transistor substrates includes a connection zone, and the connection zones are adjacent to each other.

According to one embodiment of the present disclosure, an extension direction of the thin film transistor substrates is parallel to an extension direction of the connection zones.

One aspect of the present disclosure is to provide a manufacturing method of a tiling display device.

According to one embodiment of the present disclosure, a manufacturing method of a tiling display device includes the steps as follows. A plurality of thin film transistor substrates is disposed on a support element, making the film transistor substrates adjacent to each other. A front panel laminate is disposed on the thin film transistor substrates, in which a transparent conductive layer of the front panel laminate is on a bottom surface of a light transmissive film of the front panel laminate, and a display medium layer of the front panel laminate is between the transparent conductive layer and the thin film transistor substrates. A protection sheet is disposed on a top surface of the front panel laminate.

According to one embodiment of the present disclosure, the manufacturing method further includes the steps as follows. A plurality of cutting zones are formed along edges of a plurality of active regions of a mother thin film transistor substrate, in which the cutting zones are respectively located outside the active regions. The mother thin film transistor substrate is cut along the cutting zones to form the thin film transistor substrates.

According to one embodiment of the present disclosure, the cutting zones of the mother thin film transistor substrate are cut by laser cutting.

According to one embodiment of the present disclosure, the thin film transistor substrates are disposed on the support element by an adhesion method.

According to one embodiment of the present disclosure, the thin film transistor substrates are disposed on the support element by a mask alignment mark.

In the aforementioned embodiments of the present disclosure, because only one front panel laminate is disposed on the thin film transistor substrates and only one protection sheet is disposed on the front panel laminate, a limitation of an interval (safety tolerance) between an edge of the front panel laminate and an edge of the thin film transistor substrates can be eliminated, and a limitation of an interval (safety tolerance) between an edge of the protection sheet and the edge of the thin film transistor substrates can be also eliminated. Only an interval (cutting tolerance) between the thin film transistor substrates would affect the size of the joining site, thereby significantly reducing the effect on vision. Furthermore, because only the thin film transistor substrates are spliced in the tiling display device in actual, and the front panel laminate and the protect sheet are above and cover the joining site, the effect on the vision can be further improved. The tiling display device of the present disclosure can be improved to achieve an invisible jointing site to human eye.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of a tiling display device according to one embodiment of the present disclosure;

FIG. 2 is a cross-sectional view of the tiling display device taken along line 2-2 of FIG. 1;

FIG. 3 is a partially enlarged view of a front panel laminate of FIG. 2;

FIG. 4 is an enlarged view of thin film transistor substrates of FIG. 1;

FIG. 5 is an enlarged view of thin film transistor substrates according to one embodiment of the present disclosure;

FIG. 6 is a flow chart of a manufacturing method of a tiling display device according to one embodiment of the present disclosure; and

FIG. 7 is a top view of a mother thin transistor substrate according to one embodiment of the present disclosure before being cut.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts.

A plurality of embodiments of the present disclosure is illustrated in the drawings as follows, for clear explanation, many practice details will be described in the following. However, it should be understood that the practice details are not be used to limit the present disclosure. In other words, in some embodiments of the present disclosure, these details are optional in practice. Furthermore, for simplifying the drawings, some known structures and elements will be shown in simplified illustration.

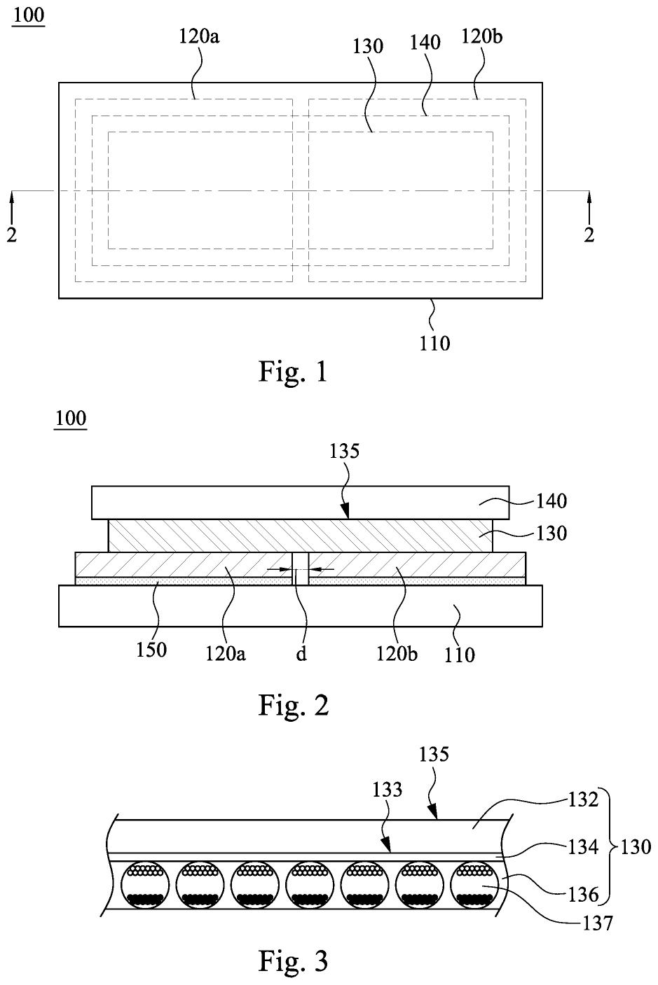

FIG. 1 is a top view of a tiling display device 100 according to one embodiment of the present disclosure. FIG. 2 is a cross-sectional view of the tiling display device taken along line 2-2 of FIG. 1. Please refer to FIG. 1 and FIG. 2, the tiling display device 100 includes a support element 110, several thin film transistor (TFT) substrates 120a, 102b, a front panel laminate (FPL) 130 and a protection sheet 140. The thin film transistor substrates 120a, 120b are located on the support element 110 and adjacent to each other. The front panel laminate 130 is located on the thin film transistor substrates 120a, 120b. In other words, one part of the front panel laminate 130 is located on the thin film transistor substrate 120a, and the other part of the front panel laminate 130 is located on the thin film transistor substrate 120b. The number of the thin film transistor substrates is not used to limit the present disclosure. Furthermore, the protection sheet 140 is located on a top surface 135 of the front panel laminate 130, that is, located on a surface of the front panel laminate 130 facing away from the thin film transistor substrates 120a and 120b.

Because the tiling display device 100 includes only one front panel laminate 130 located on the thin film transistor substrates 120a, 120b and only one protection sheet 140 located on the front panel laminate 130, a limitation of an interval (safety tolerance) between an edge of the front panel laminate and an edge of the thin film transistor substrate can be eliminated, and a limitation of an interval (safety tolerance) between an edge of the protection sheet and the edge of the thin film transistor substrate can be also eliminated, without being worried about that two adjacent front panel laminates or two adjacent protection sheets in a traditional tiling display device are rubbed, impacted, or overlapped with each other so as to need to purposely separate to further affect vision effect.

As a result, only an interval d (cutting tolerance) between the thin film transistor substrates 120a, 120b in the tiling display device 100 would affect a size of a joining site, thereby significantly reducing the effect on vision. Furthermore, since only the thin film transistor substrates 120a, 120b are spliced in the tiling display device 100 in actual, and the front panel laminate 130 and the protect sheet 140 are above and cover the joining site, the effect on the vision can be further improved.

The tiling display device 100 of the present disclosure can be improved to have an invisible joining site to human eye. In the present embodiment, the interval d between two adjacent thin film transistor substrates 120a, 120b may be in a range from 10 μm to 200 μm. When the interval d is reduced to an interval under 50 μm, an invisible joining site to human eye is achieved.

In addition, the tiling display device 100 further includes an adhesive layer 150. The adhesive layer 150 is located between the thin film transistor substrates 120a, 120b and the support element 110. The adhesive layer 150 may be an optical clear adhesive (OCA) or a double-side adhesive. The optical clear adhesive may be coated on bottom surfaces of the thin film transistor substrates 120a, 120b or a top surface of the support element 110, and the present disclosure is not limited in this regard.

In the present embodiment, the support element 110 may be a flexible substrate. The support element 110 may be made of a material including glass, acrylic, carbon fiber, graphene, or metal. Furthermore, as shown in FIG. 1, an area of the support element 110 is greater than a total area of the thin film transistor substrates 120a, 120b. The total area of the thin film transistor substrates 120a, 120b is greater than an area of the protection sheet 140, and the area of the protection sheet 140 is greater than an area of the front panel laminate 130. The front panel laminate 130 may be, but not limited to a microcapsule-type display panel, a MicroCup-type display panel or other suitable display panel.

FIG. 3 is a partially enlarged view of the front panel laminate 130 of FIG. 2. Please refer to FIG. 2 and FIG. 3, the front panel laminate 130 includes a light transmissive film 132, a transparent conductive layer 134, and a display medium layer 136. The transparent conductive layer 134 is located on a bottom surface 133 of the light transmissive film 132. In the present embodiment, the material of the transparent conductive layer 134 may include an indium tin oxide (ITO), but the present disclosure is not limited in this regard. The display medium layer 136 is located between the transparent conductive layer 134 and the thin film transistor substrate 120a, and is located between the transparent conductive layer 134 and the thin film transistor substrate 120b. The display medium layer 136 includes a plurality of microcapsules 137, and each microcapsule 137 has a plurality of charged particles therein, such as black particles and white particles, but the present disclosure is not limited in this regard.

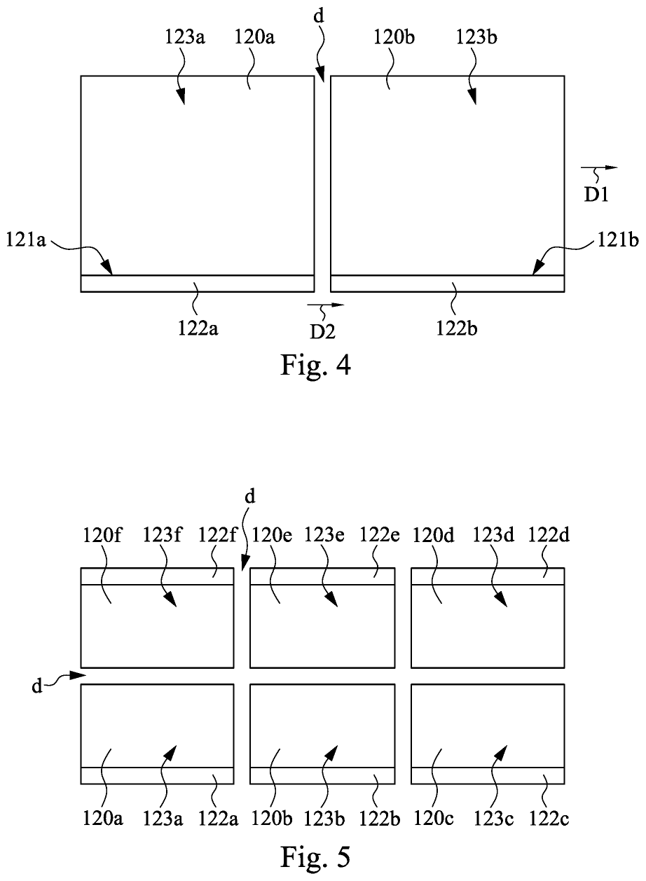

FIG. 4 is an enlarged view of the thin film transistor substrates 120a, 120b of FIG. 1. In the present embodiment, a lower edge 121a of the thin film transistor substrate 120a includes a connection zone 122a, a lower edge 121b of the thin film transistor substrate 120b includes a connection zone 122b, and the connection zones 122a, 122b are adjacent to each other. The connection zones 122a, 122b may be electrically connected to an external electronic device for controlling an active region (i.e., a pixel region) 123a of the thin film transistor substrate 120a and an active region 123b of the thin film transistor substrate 120b. Furthermore, an extension direction D1 (i.e., the direction of the spliced length) of the thin film transistor substrates 120a, 120b is parallel to an extension direction D2 of the connection zones 122a, 122b, and the present disclosure is not limited by the spliced number of the thin film transistor substrates 120a and 120b.

FIG. 5 is an enlarged view of thin film transistor substrates 120a, 120b, 120c, 120d, 120e, 120f according to one embodiment of the present disclosure. The difference between this embodiment and the embodiment of FIG. 4 is that the number of the thin film transistor substrates 120a, 120b, 120c, 120d, 120e, 120f is six. In the present embodiment, connection zones 122d, 122e, 122f of the thin film transistor substrates 120d, 120e, 120f are respectively at upper edges of the thin film transistor substrates 120d, 120e, 120f, and connection zones 122a, 122b, 122c of the thin film transistor substrates 120a, 120b, 120c are respectively at lower edges of the thin film transistor substrates 120a, 120b, 120c. The interval d between two of the thin film transistor substrates 120a, 120b, 120c, 120d, 120e, 120f adjacent to each other not only may extend along a horizontal direction, but also may extend along a vertical direction. The interval d may be in a range from 10 μm to 200 μm. When the interval d is reduced to an interval under 50 μm, an invisible joining site to human eye is achieved. Furthermore, the thin film transistor substrates 120a, 120b, 120c, 120d, 120e, 120f respectively include active regions 123a, 123b, 123c, 123d, 123e, 123f capable of displaying a larger spliced image than that of FIG. 4.

It should be understood that the connection relationship, materials and advantages of the aforementioned elements will not be described again. In the following description, a manufacturing method of the tiling display device 100 of FIG. 1 will be described.

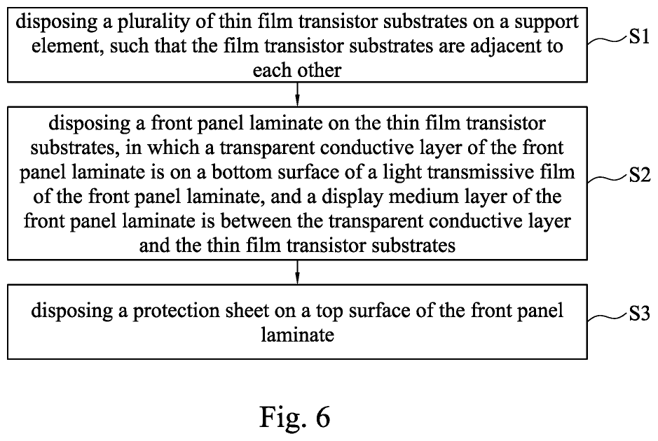

FIG. 6 is a flow chart of a manufacturing method of a tiling display device according to one embodiment of the present disclosure. The manufacturing method of the tiling display device includes the following steps. First, in step S1, a plurality of thin film transistor substrates are disposed on a support element, such that the thin film transistor substrates are adjacent to each other. Next, in step S2, a front panel laminate is disposed on the thin film transistor substrates, in which a transparent conductive layer of the front panel laminate is on a bottom surface of a light transmissive film of the front panel laminate, and a display medium layer of the front panel laminate is between the transparent conductive layer and the thin film transistor substrates. Then, in step S3, a protection sheet is disposed on a top surface of the front panel laminate.

In the following description, the foregoing steps will be explained.

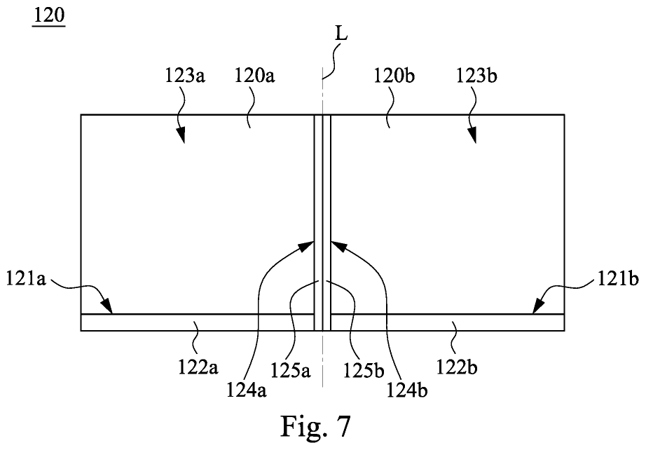

FIG. 7 is a top view of a mother thin transistor substrate 120 according to one embodiment of the present disclosure before being cut. Before the step S1 of FIG. 6, a plurality of cutting zones 125a, 125b are formed respectively along the edges 124a, 124b of the active regions 123a, 123b of the mother thin film transistor substrates 120. The cutting zones 125a, 125b are located outside the active regions 123a, 123b, respectively. The cutting zone 125a may be a reserved pixel region at the right side of the active region 123a, and the cutting zone 125b may be a reserved pixel region at the left side of the active region 123b. Next, the mother thin film transistor substrate 120 is cut along the cutting zones 125a, 125b (i.e., along line L) so as to form the thin film transistor substrates 120a, 120b. In the present embodiment, the cutting zones 125a, 125b of the mother thin film transistor substrate 120 are cut by laser cutting.

Please refer to FIG. 2 and FIG. 6, after the thin film transistor substrates 120a, 120b are obtained, the thin film transistor substrates 120a, 120b are disposed on the support element 110, such that the thin film transistor substrates 120a, 120b are adjacent to each other. In the present embodiment, the thin film transistor substrates 120a, 120b may be disposed on the support element 110 by adhesion. For example, the support element 110 and the thin film transistor substrates 120a, 120b are adhered by an optical transparent adhesive or a double-side adhesive of the adhesive layer 150. In the step S1, in order to further reduce the interval d of FIG. 2, the thin film transistor substrates 120a, 120b may be precisely disposed on the support element 110 by a mask alignment mark.

Next, in the step S2, the front panel laminate 130 is disposed on the thin film transistor substrates 120a, 120b. The transparent conductive layer 134 (see FIG. 3) of the front panel laminate 130 is located on the bottom surface 133 of the light transmissive film 132 of the front panel laminate 130, and the display medium layer 136 (see FIG. 3) of the front panel laminate 130 is between the transparent conductive layer 134 and the thin film transistor substrates 120a, 120b. Then, in the step S3, the protection sheet 140 would be disposed on the top surface 135 of the front panel laminate 130, so as to obtain the tiling display device 100 of FIG. 1.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A tiling display device, comprising:
a support element;
a plurality of thin film transistor substrates located on the support element and adjacent to each other;
a front panel laminate located on the thin film transistor substrates and comprising a light transmissive film, a transparent conductive layer, and a display medium layer, wherein the transparent conductive layer is located on a bottom surface of the light transmissive film, and the display medium layer is located between the transparent conductive layer and the thin film transistor substrates; and
a protection sheet located on a surface of the front panel laminate facing away from the thin film transistor substrates.

2. The tiling display device of claim 1, wherein an interval between the two adjacent thin film transistor substrates is in a range from 10 μm to 200 μm.

3. The tiling display device of claim 1, further comprising:
an adhesive layer located between the thin film transistor substrates and the support element.

4. The tiling display device of claim 3, wherein the adhesive layer is an optical clear adhesive or a double-side adhesive.

5. The tiling display device of claim 1, wherein the support element is a flexible substrate.

6. The tiling display device of claim 1, wherein the support element is made of a material comprising glass, acrylic, carbon fiber, graphene or metal.

7. The tiling display device of claim 1, wherein an area of the support element is greater than a total area of the thin film transistor substrates.

8. The tiling display device of claim 1, wherein a total area of the thin film transistor substrates is greater than an area of the protection sheet, and the area of the protection sheet is greater than an area of the front panel laminate.

9. The tiling display device of claim 1, wherein an edge of each of thin film transistor substrates comprises a connection zone, and the connection zones are adjacent to each other.

10. The tiling display device of claim 9, wherein an extension direction of the thin film transistor substrates is parallel to an extension direction of the connection zones.

11. A manufacturing method of a tiling display device, comprising:
disposing a plurality of thin film transistor substrates on a support element, such that the film transistor substrates adjacent to each other;
disposing a front panel laminate on the thin film transistor substrates, wherein a transparent conductive layer of the front panel laminate is on a bottom surface of a light transmissive film of the front panel laminate, and a display medium layer of the front panel laminate is between the transparent conductive layer and the thin film transistor substrates; and
disposing a protection sheet on a top surface of the front panel laminate.

12. The manufacturing method of claim 11, further comprising:
forming a plurality of cutting zones along edges of a plurality of active regions of a mother thin film transistor substrate, wherein the cutting zones are respectively located outside the active regions; and
cutting the mother thin film transistor substrate along the cutting zones to form the thin film transistor substrates.

13. The manufacturing method of claim 12, wherein the cutting zones of the mother thin film transistor substrate are cut by laser cutting.

14. The manufacturing method of claim 11, wherein the thin film transistor substrates are disposed on the support element by adhesion.

15. The manufacturing method of claim 11, wherein the thin film transistor substrates are disposed on the support element by a mask alignment mark.
